(19) United States
(12) Patent Application Publication
(10) Pub. No.: US 2026/0109649 A1
(43) Pub. Date: Apr. 23, 2026

(54) PIEZOELECTRIC MATERIAL COMPOSITION AND PREPARATION METHOD THEREOF

(71) Applicant: KOREA INSTITUTE OF SCIENCE AND TECHNOLOGY, Seoul (KR)

(72) Inventors: Hyun-Cheol Song, Seoul (KR); Chong Yun Kang, Seoul (KR); Sunghoon Hur, Seoul (KR); Dong-Gyu Lee, Seoul (KR); Seong Keun Kim, Seoul (KR); Ji-Won Choi, Seoul (KR); Jin Sang Kim, Seoul (KR); Tae Heon Kim, Seoul (KR)

(21) Appl. No.: 18/940,543

(22) Filed: Nov. 7, 2024

(30) Foreign Application Priority Data
Oct. 22, 2024 (KR) 10-2024-0144831

(51) Int. Cl. C04B 35/499; C04B 35/626; C04B 35/64; H10N 30/092; H10N 30/85

(52) U.S. Cl. CPC C04B 35/499; C04B 35/62625; C04B 35/64; H10N 30/092; H10N 30/852; C04B 2235/3234; C04B 2235/3255; C04B 2235/3262; C04B 2235/6025; C04B 2235/656; C04B 2235/6583; C04B 2235/768; C04B 2235/85

(57) ABSTRACT

A piezoelectric material composition includes a first material doped with 2 mol % to 3 mol % of Mn based on 100 mol % of the total composition, and represented by [Formula 1] as (1−x)Pb(Mg_{2/3}Nb_{1/3})O₃-xPbTiO₃ wherein the x is 0.21 to 0.25. A method for preparing a piezoelectric material composition includes: mixing MgNb₂O₆ and PbO, TiO₂, and MnO₂ to form a first material doped with Mn and represented by Formula 1 above; mixing the first material and a second material in a solvent to prepare a slurry; tape-casting the slurry to form a piezoelectric sheet; laminating the piezoelectric sheet; and sintering the piezoelectric sheet in an oxygen atmosphere.

### CROSS-REFERENCE TO RELATED APPLICATION

This U.S. non-provisional patent application claims priority under 35 U.S.C. § 119 of Korean Patent Application No. 10-2024-0144831, filed on Oct. 22, 2024, in the Korean Intellectual Property Office, the entire contents of which are hereby incorporated by reference.

### BACKGROUND

The present disclosure herein relates to a piezoelectric material composition and a preparation method thereof.

A piezoelectric material may convert electrical energy into mechanical energy, and mechanical energy into electrical energy. Accordingly, the piezoelectric material is used as a smart material in various industrial fields such as ultrasound devices, medical devices, communication devices, transducers, sensors, and the like.

A piezoelectric material having a high piezoelectric constant (d₃₃) and a low mechanical quality factor (Qₘ) is referred to as a soft piezoelectric material, and conversely, a piezoelectric material having a low piezoelectric constant (d₃₃) and a high mechanical quality factor (Qₘ) is referred to as a hard piezoelectric material.

It is very difficult to develop a piezoelectric material having both a high piezoelectric constant (d₃₃) and a high mechanical quality factor (Qₘ). However, a piezoelectric material having a high piezoelectric constant (d₃₃) and a high mechanical quality factor (Qₘ) has been developed to be applied in a wide range of industries.

### SUMMARY

The present disclosure provides a piezoelectric material composition having both a high piezoelectric constant (d₃₃) and a high mechanical quality factor (Qₘ).

An embodiment of the inventive concept provides a piezoelectric material composition including a first material doped with 2 mol % to 3 mol % of Mn based on 100 mol % of the total composition, and represented by [Formula 1] below.

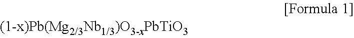

In an embodiment, the x may be 0.21 to 0.25.

In an embodiment of the inventive concept, a piezoelectric material composition includes a plurality of grains, wherein each of the plurality of grains may be distinguished from each other by a grain boundary, and each of the plurality of grains may include a first material doped with 2 mol % to 3 mol % of Mn based on 100 mol % of the total composition, and represented by Formula 1 below.

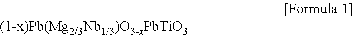

In an embodiment, the x may be 0.21 to 0.25.

In an embodiment of the inventive concept, a method for preparing a piezoelectric material includes mixing MgNb₂O₆ and PbO, TiO₂, and MnO₂ to form a first material doped with Mn and represented by Formula 1 below, mixing the first material and a second material in a solvent to prepare a slurry, tape-casting the slurry to form a piezoelectric sheet, laminating the piezoelectric sheet, and sintering the piezoelectric sheet in an oxygen atmosphere, wherein 2 mol % to 3 mol % of the Mn may be doped based on 100 mol % of the first material, the second material may be a seed having a perovskite structure, and the content of the second material may be 0.5 vol % to 1.5 vol % based on 100 vol % of the slurry.

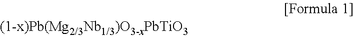

In an embodiment, the x may be 0.21 to 0.25.

### BRIEF DESCRIPTION OF THE FIGURES

The patent or application file contains at least one drawing executed in color. Copies of this patent or patent application publication with color drawing(s) will be provided by the Office upon request and payment of the necessary fee.

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a piezoelectric material composition according to embodiments of the present invention;

FIG. 2 is a flowchart of a method for preparing the piezoelectric material composition according to embodiments of the present invention;

FIG. 3 and FIG. 4 show results of X-ray diffraction analysis;

FIG. 5 shows results of piezoelectric performance index analysis;

FIG. 6 shows results of electron backscatter diffraction pattern analysis;

FIG. 7 shows results of scanning electron microscopy (SEM) analysis;

FIG. 8 shows results of measuring a density according to a seed content;

FIG. 9 shows results of measuring a mechanical quality factor according to a seed content;

FIG. 10 shows results of evaluating electrical properties according to a seed content;

FIG. 11 shows results of measuring a vibration rate according to an electric field change;

FIG. 12 shows results of measuring a temperature change according to a vibration rate; and

FIG. 13 shows results of piezoelectric performance index analysis of Examples and Comparative Examples.

### DETAILED DESCRIPTION

Hereinafter, embodiments of the inventive concept will be described with reference to the accompanying drawings to describe the inventive concept in detail.

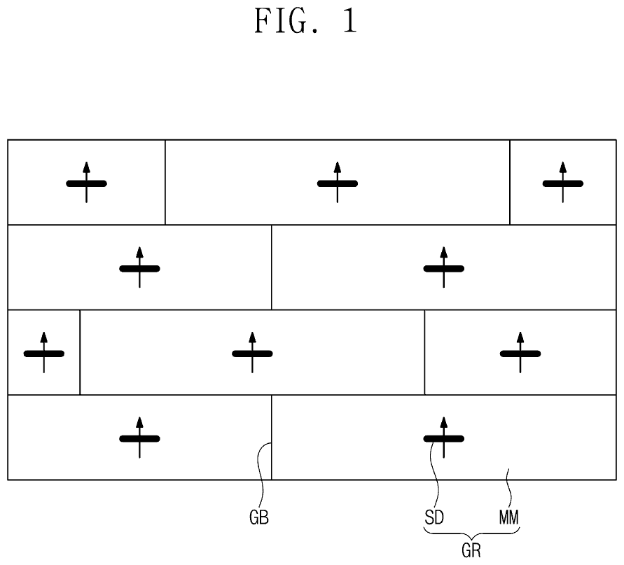

FIG. 1 is a cross-sectional view of a piezoelectric material composition according to embodiments of the present invention.

Referring to FIG. 1, the piezoelectric material composition may include a plurality of grains GR. Each of the plurality of grains GR may be distinguished from each other by a grain boundary GB. Each of the plurality of grains GR may include a first material MM represented by Formula 1 below. The piezoelectric material composition may be doped with manganese (Mn). 2 mol % to 3 mol % of the manganese (Mn) may be doped based on 100 mol % of the total composition. 2 mol % of the Mn may be doped based on 100 mol % of the total composition. If the doping content of the Mn is greater than 3 mol % based on 100 mol % of the total composition, the manganese (Mn) may be doped non-uniformly. If the doping content of the Mn is less than 2 mol % based on 100 mol % of the total composition, an effect due to the doping of the manganese (Mn) may not be exhibited. Furthermore, the mechanical quality factor of the piezoelectric material composition may be decreased.

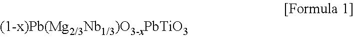

In this case, as an example, the x may be 0.21 to 0.25. As an example, the x may be 0.23. If the x is larger than 0.25, the mechanical quality factor of the piezoelectric material composition may be lowered. If the content of PbTiO₃ in the piezoelectric material composition is increased, the volume fraction of a trigonal grain structure may increase, so that the mechanical quality factor may be lowered. If the x is smaller than 0.21, the Curie temperature (Tc) may be low.

The piezoelectric material composition according to embodiments of the present invention may be doped with manganese (Mn). Due to the effect of doping the manganese (Mn), the piezoelectric material composition may provide a high mechanical quality factor.

The first material MM may have at least one of a trigonal, monoclinic, or tetragonal grain structure. The first material MM may include a monoclinic grain structure. The space group of the monoclinic grain structure may include Cm and Pm. In this case, the volume fraction of a grain having a Cm space group may be greater than the volume fraction of a grain having a Pm space group. The Cm space group may be 80 vol % to 89 vol % based on 100 vol % of the first material. The Pm space group may be 11 vol % to 20 vol % based on 100 vol % of the first material.

Each of the plurality of grains may further include a second material SD. The second material SD may be disposed inside the first material MM. The second material SD may be surrounded by the first material MM. The second material SD may be positioned at a central portion of the first material MM.

The second material SD may be a seed. The second material SD may be a seed having a perovskite (ABO₃) structure, and as an example, may include BaTiO₃. The second material SD may be a seed in which grains are aligned in a (001) direction. The first material MM may be grown from the second material SD by a reaction. That is, the first material MM may be grown based on a grain direction of the second material SD. The first material MM may be grown by a template grain growth method using the second material SD as a seed. Accordingly, the first material MM may have a perovskite structure, and the first material MM may have a (001) grain direction.

The content of the second material SD may be 0.5 vol % to 2.5 vol % based on 100 vol % of the piezoelectric material composition, and as an example, may be 1.5 vol %. If the content of the second material SD is less than 0.5 vol %, the first material MM may have a non-uniform grain structure. The content of the second material SD acting as a seed may be too low to control the grain direction of the first material MM.

If the content of the second material SD is greater than 2.5 vol %, the mechanical quality factor of the piezoelectric material composition may be decreased. Since the content of the first material MM, which is a mother material, is reduced, the mechanical quality factor may be decreased.

As an example, the porosity of the piezoelectric material composition may be 0.1% to 3%. The piezoelectric material composition according to the present invention may have a low porosity. The piezoelectric material composition may have a high density, and a piezoelectric material composition having a high mechanical quality factor may be provided.

The piezoelectric constant (d₃₃) of the piezoelectric material composition may be 350 pC/N to 450 pC/N. The mechanical quality factor (Qₘ) of the piezoelectric material composition may be 1400 to 2500.

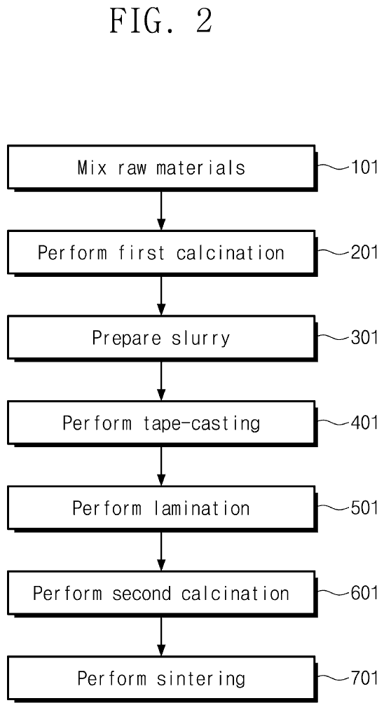

FIG. 2 shows diagrams for showing a method for preparing the piezoelectric material composition according to embodiments of the present invention. In order to simplify the description, the same descriptions as those described with reference to FIG. 1 will be omitted.

Referring to FIG. 2, the method for preparing the piezoelectric material composition may include a raw-material mixing step 101. In the raw-material mixing step 101, MgNb₂O₆ may be formed first. In order to prevent magnesium (Mg) and niobium (Nb) from reacting with lead (Pb), thereby forming a pyrochlore phase, the MgNb₂O₆ may be formed first. As an example, the forming of the MgNb₂O₆ may include heating MgO at 1000° C. for 2 hours, mixing the MgO and Nb₂O₅ with ethanol to form a first mixture, ball-milling the first mixture, and heating the first mixture at 1100° C. for 4 hours.

The MgNb₂O₆ and PbO, TiO₂, and MnO₂ may be mixed to form a second mixture. As an example, the content of the MnO₂ may be 2 mol % to 3 mol % based on 100 mol % of the second mixture.

The method for preparing the piezoelectric material composition may include a first milling step. As an example, the first milling step may include ball-milling the second mixture for 25 hours.

Thereafter, a first calcination step 201 may be performed. As an example, the first calcination step 201 may include heating the primarily ball-milled second mixture at 800° C. for 4 hours, mixing the heated second mixture with a binder to form a third mixture, pressing the third mixture (e.g., 50 MPa) into a pellet form, heating the pellet at 600° C. for 2 hours, at 1250° C. for 2 hours, and at 800° C. for 4 hours to form powder. A first material represented by [Formula 1] below may be formed by the above-described first calcination step. The first material may be doped with 2 mol % to 3 mol % of manganese (Mn) based on 100 mol % of the first material. As an example, 2 mol % of the Mn may be doped based on 100 mol % of the first material.

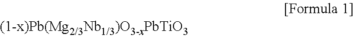

In this case, as an example, the x may be 0.21 to 0.25. As an example, the x may be 0.23.

The method for preparing the piezoelectric material composition may include a slurry preparation step 301. The preparing of the slurry may include mixing a sintering agent, toluene, ethanol, a dispersant, a binder, and a second material with the first material. The second material may be a seed having a perovskite structure, and as an example, may include BaTiO₃. The second material may be a seed in which grains are aligned in the 001 direction. The content of the second material may be 0.5 vol % to 2.5 vol % based on 100 vol % of the slurry, and as an example, may be 1.5 vol %.

A tape-casting step 401 may be performed. The tape-casting may include applying the slurry on a sheet at a rate of 0.4 m/min, and drying the sheet at room temperature for 24 hours. A piezoelectric sheet may be formed by the above-described tape-casting.

A lamination step 501 may be performed. The lamination may include notching the piezoelectric sheet, stacking the notched piezoelectric sheets, and compressing the stacked piezoelectric sheets at 20 MPa at 65° C. for 30 minutes.

A second calcination step 601 may be performed. The second calcination step may include heating the compressed piezoelectric sheets at 330° C. for 12 hours, and heating the heated piezoelectric sheet at 550° C. for 3 hours. An organic material in the piezoelectric sheets may be removed by the above-described second calcination step.

Cold isostatic pressing may be performed. The cold isostatic pressing may include compressing the piezoelectric sheet at 200 MPa for 20 minutes. By the cold isostatic pressing, the binding force between compositions in the piezoelectric sheets may be improved.

A sintering process step 701 may be performed. The sintering process may be performed in an oxygen atmosphere. As an example, the sintering process may be performed at 1100° C. to 1300° C. As an example, the sintering process may include performing heating at 1250° C. for 10 hours. By the above-described sintering process, grains of the first material may be grown from the second material. A piezoelectric material composition may be formed by the above-described sintering process.

Since the sintering process is performed in an oxygen atmosphere, the porosity of the piezoelectric material composition may be lowered, and the density of the piezoelectric material composition may be improved. Oxygen may diffuse rapidly, and thus, may escape from the piezoelectric material composition. The porosity of the piezoelectric material composition may be lowered. Therefore, a piezoelectric material composition having a high mechanical quality factor may be provided.

Hereinafter, the present invention will be described with reference to Examples and Comparative Examples.

### Example 1

MgO was heated at 1000° C. for 2 hours. The MgO and Nb₂O₅ were mixed with ethanol to form a first mixture. The molar ratio of MgO and Nb₂O₅ was 1:1. The first mixture was ball-milled and then the first mixture was heated at 1100° C. for 4 hours to form MgNb₂O₆. The MgNb₂O₆ and PbO, TiO₂, and MnO₂ were mixed to form a second mixture. The molar ratio of MgNb₂O₆ and PbO, and TiO₂ was 0.26:1:0.21. The content of the MnO₂ was 2 mol % based on 100 mol % of the second mixture. The second mixture was ball-milled for 25 hours. Thereafter, the second mixture was heated at 800° C. for 4 hours. The heated second mixture was mixed with a binder to form a third mixture. PVA was used as the binder, and the content of the binder was 5 vol % based on 1000 vol % of the third mixture. The third mixture was pressed at 50 MPa to form a pellet. The pellet was heated at 600° C. for 2 hours, and then heated at 1250° C. for 2 hours. Thereafter, the pellet was heated at 800° C. for 4 hours to form powder. As a result, a first material was formed.

Thereafter, the first material was mixed with a sintering agent, toluene, ethanol, a dispersant, and a BaTiO₃ seed to form a fourth mixture. BYK-111 was used as the dispersant. Thereafter, PVA was added to the fourth mixture to form a slurry. The content of the PVA was 35 wt % based on 100 wt % of the fourth mixture. The content of the BaTiO₃ was 1.5 vol % based on 100 vol % of the slurry. The slurry was stirred at 800 rpm in a vacuum state for 10 minutes. The slurry was applied on a sheet at a rate of 0.4 m/min and then the sheet was dried at room temperature for 24 hours. The thickness of the sheet was 50 μm. The sheet applied with the slurry was notched to a size of 10×10 cm². The notched sheets were laminated and then compressed at 20 MPa using a hot press machine at 65° C. for 30 minutes. Thereafter, the compressed sheets were subdivided into 12 pellets using a laser cutting machine. The pellets were heated using a heater. Specifically, the temperature of the heater was raised to 330° C. at 0.3° C./min, and then the pellets were heated for 12 hours. After the temperature reached 550° C., the pellets were heated for 3 hours.

Thereafter, the pellets were sealed using latex and then subjected to cold isostatic pressing at 200 MPa for 20 minutes. Thereafter, the pellets were heated in an oxygen atmosphere at 1250° C. for 10 hours to form a piezoelectric material composition.

As a result, a piezoelectric material composition represented by a formula of 0.79Pb(Mg_{2/3}Nb_{1/3})O₃-0.21PbTiO₃ doped with 2 mol % of Mn based on the total composition was formed.

### Example 2

A piezoelectric material composition was formed in the same manner as in Example 1, except that the molar ratio of MgNb₂O₆ and PbO, and TiO₂ was 0.26:1:0.23. As a result, a piezoelectric material composition represented by a formula of 0.77Pb(Mg_{2/3}Nb_{1/3})O₃-0.23PbTiO₃ doped with 2 mol % of Mn based on the total composition was formed.

### Example 3

A piezoelectric material composition was formed in the same manner as in Example 1, except that the molar ratio of MgNb₂O₆ and PbO, and TiO₂ was 0.25:1:0.25. As a result, a piezoelectric material composition represented by a formula of 0.75Pb(Mg_{2/3}Nb_{1/3})O₃-0.25PbTiO₃ doped with 2 mol % of Mn based on the total composition was formed.

### Example 4

A piezoelectric material composition was formed in the same manner as in Example 1, except that the molar ratio of MgNb₂O₆ and PbO, and TiO₂ was 0.24:1:0.27. As a result, a piezoelectric material composition represented by a formula of 0.73Pb(Mg_{2/3}Nb_{1/3})O₃-0.27PbTiO₃ doped with 2 mol % of Mn based on the total composition was formed.

### Comparative Example 1

A piezoelectric material composition was formed in the same manner as in Example 1, except that MnO₂ and a BaTiO₃ seed were not used. As a result, a piezoelectric material composition represented by a formula of 0.79Pb(Mg_{2/3}Nb_{1/3})O₃-0.21PbTiO₃ was formed.

### Comparative Example 2

A piezoelectric material composition was formed in the same manner as in Example 1, except that sintering was performed in a general air atmosphere. As a result, a piezoelectric material composition represented by a formula of 0.79Pb(Mg_{2/3}Nb_{1/3})O₃-0.21PbTiO₃ doped with 2 mol % of Mn based on the total composition was formed.

### Comparative Example 3

A piezoelectric material composition represented by a formula of Pb[Zr_{0.52} Ti_{0.48}]O₃ was prepared.

### Comparative Example 4

A piezoelectric material composition represented by a formula of PbTiO₃ was prepared.

### Comparative Example 5

A piezoelectric material composition represented by a formula of KnbO₃ was prepared.

### Evaluation Example 1: X-Ray Diffraction Analysis

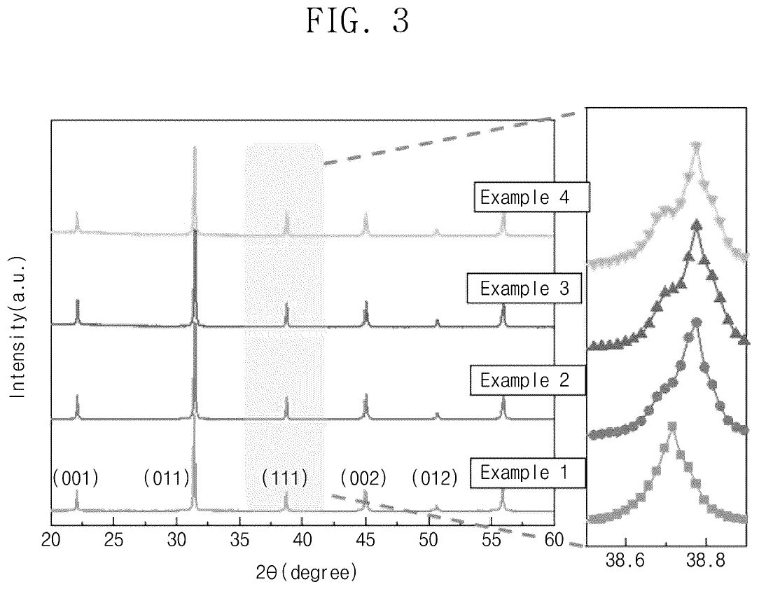

FIG. 3 and FIG. 4 show results of XRD analysis using Cu Kα rays for Example 1 to Example 4. Referring to FIG. 3 and FIG. 4, it can be confirmed that Example 1 to Example 4 all have a single-phase perovskite structure. Referring to FIG. 3, it can be confirmed that Example 1 to Example 4 have peaks between 38.6° and 38.9°. More specifically, Example 1 has a peak between 38.6° and 38.9°, which is distinguished from those of Example 2 to Example 4.

It can be confirmed that as the fraction of PT increases in PMN-PT, a trigonal grain structure changes into a monoclinic grain structure. Referring to FIG. 4, it can be confirmed that Example 1 has a trigonal structure. It can be confirmed that Examples 2 to 4 have a monoclinic structure, and that space groups Cm and Pm coexist.

It can be confirmed that as the fraction of PT increases in PMN-PT (i.e., from Example 2 to Example 4), the volume fraction of Cm decreases. It can be confirmed that the volume fraction of Cm decreases from 89% to 81%. In addition, it can be confirmed that the volume fraction of Pm increases. It can be confirmed that the volume fraction of Pm increases from 11% to 19%. That is, it can be confirmed that as the volume fraction of PT increases, the volume fraction of the space group Pm of the monoclinic structure increases.

### Evaluation Example 2: Comparison of Piezoelectric Performance Indices

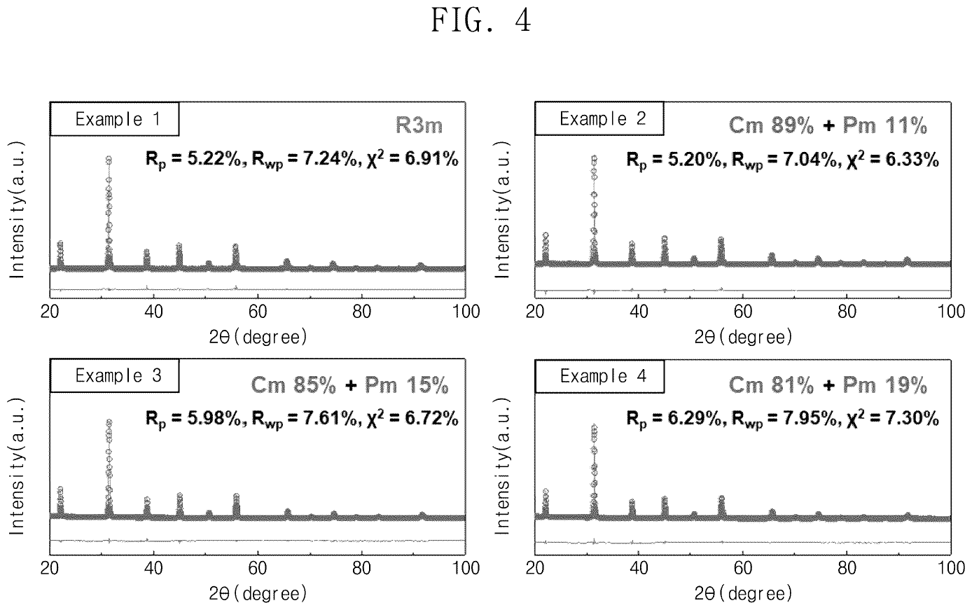

FIG. 5 and Table 1 show the results of measuring piezoelectric performance indices of Examples 1 to 4.

TABLE 1

| | Piezoelectric constant | Mechanical | |
|---|---|---|---|
| | (d₃₃) | quality factor | Curie temperature |
| Example 1 | 277 pC/N | 2793 | 111° C. |
| Example 2 | 271 pC/N | 1548 | 121° C. |
| Example 3 | 265 pC/N | 2066 | 130° C. |
| Example 4 | 265 pC/N | 1600 | 139° C. |

Referring to FIG. 5 and Table 1, it can be confirmed that the piezoelectric constant (d₃₃) changes slightly according to a change in the fraction of PT. It can be confirmed that as the fraction of PT increases, the Curie temperature (Q_{c}) increases. It can be confirmed that this is because the Curie temperature (Q_{c}) of PT is higher than the Curie temperature (Q_{c}) of PMN.

It can be seen that as the fraction of PT increases, the mechanical quality factor (Qₘ) decreases. This is because as the fraction of PT increases, the fraction of a monoclinic grain structure increases more than the fraction of a trigonal grain structure. Furthermore, in the case of a monoclinic structure, it can be confirmed that the greater the fraction of the space group Cm than the fraction of the space group Pm, the higher the mechanical quality factor.

### Evaluation Example 3: Electron Backscatter Diffraction Pattern Analysis

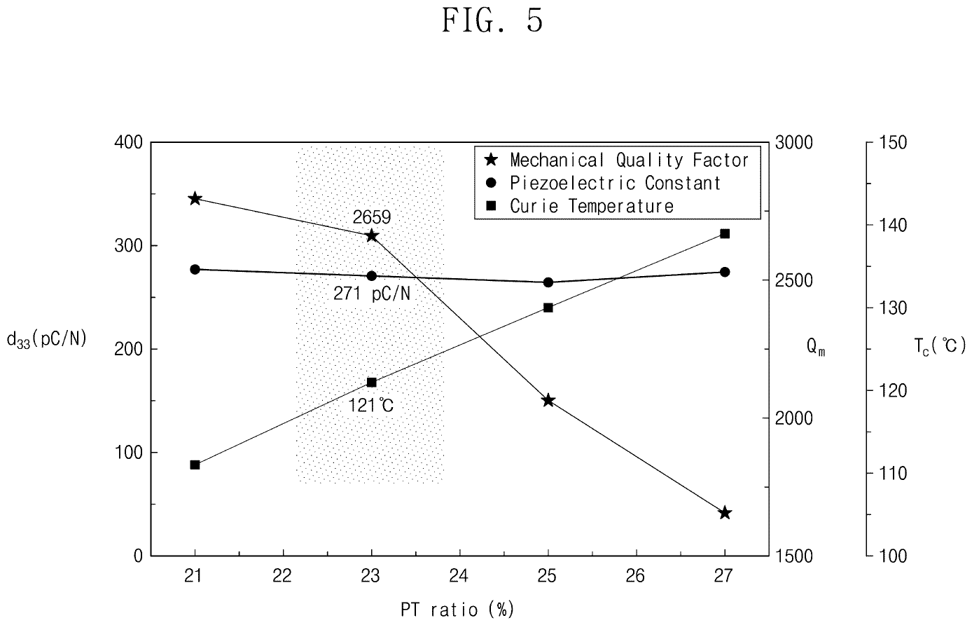

FIG. 6 shows results of electron backscatter diffraction pattern analysis of Example 1 and Comparative Example 1. Referring to FIG. 6, unlike Comparative Example 1, Example 1 was prepared by a template grain growth method, so that it can be confirmed that all of the grains are oriented in the (001) direction.

### Evaluation Example 4: Scanning Electron Microscopy Analysis

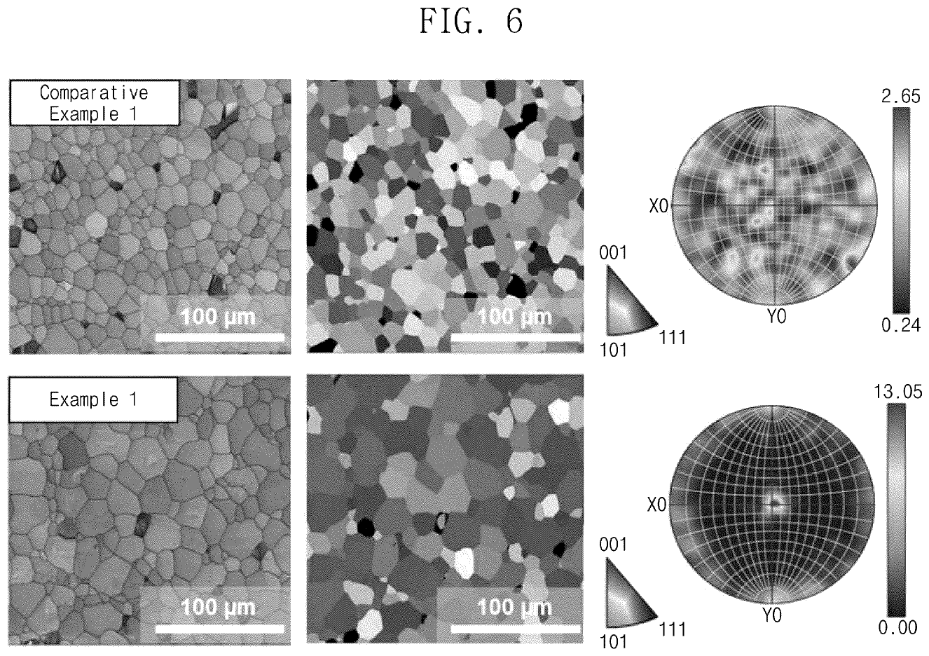

FIG. 7 shows results of SEM analysis of Comparative Example 2 and Example 1. Referring to FIG. 7, it can be confirmed that pores of Example 1 are significantly smaller than those of Comparative Example 2. It can be confirmed that this is because in the case of Example 1, sintering was performed in an oxygen atmosphere, so that the porosity is low. In the case of Comparative Example 2, it can be confirmed that the porosity is high due to nitrogen (N₂) included in a large amount in the air.

### Evaluation Example 5: Density According to Seed Content

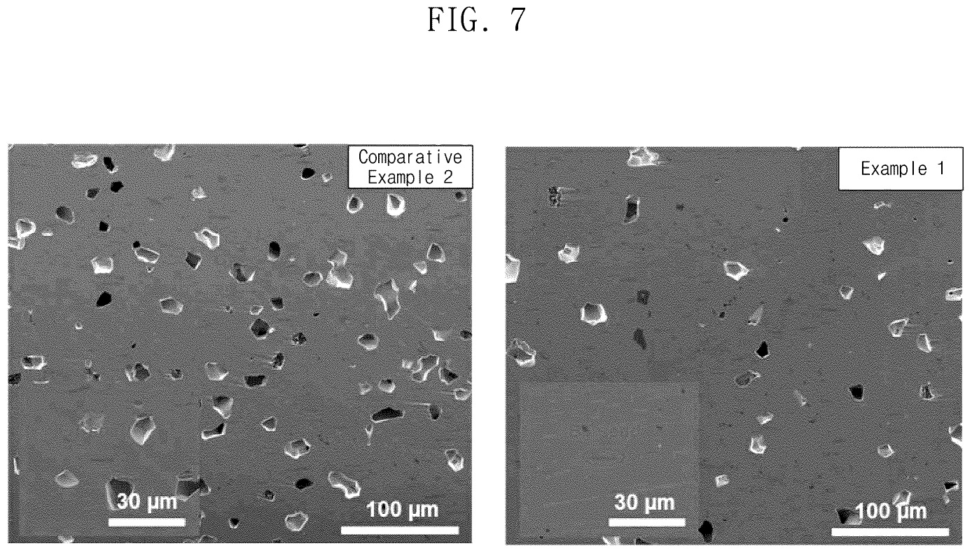

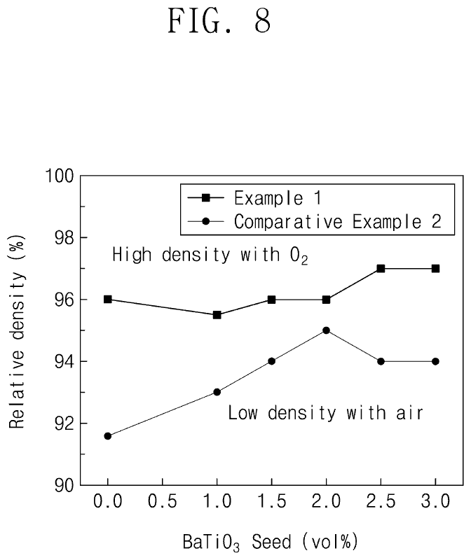

FIG. 8 shows the results of measuring relative densities of Example 1 and Comparative Example 2 while varying the BaTiO₃ seed content. The above relative density was measured by ((measured density)/(theoretical density))×100. FIG. 9 shows the results of measuring mechanical quality factors of Example 1 and Comparative Example 2 while varying the BaTiO₃ seed content. Piezoelectric material compositions were formed by setting the BaTiO₃ seed content in Example 1 and Comparative Example 2 respectively to 0.0 vol %, 0.5 vol %, 1.0 vol %, 1.5 vol %, 2.0 vol %, 2.5 vol %, and 3.0 vol % based on 100 vol % of the slurry.

Referring to FIG. 8, it can be confirmed that the relative density of Example 1 is higher than the relative density of Comparative Example 2. That is, in the case of Example 1, the sintering was performed in an oxygen atmosphere, so that the relative density is high. In the case of Example 1, it can be confirmed that this is because oxygen is quickly removed from the inside of the piezoelectric material composition to the outside thereof.

In the case of Comparative Example 2, it can be confirmed that the sintering was performed in a general air atmosphere, so that the relative density is lower than that of Example 1. In the case of Comparative Example 2, it can be confirmed that this is because the nitrogen was not removed from the inside of the piezoelectric material composition to the outside thereof, so that a large number of pores were formed.

In both Example 1 and Comparative Example 2, it can be confirmed that the relative density increases in proportion until the seed content becomes 2 vol %, and then decreases when the seed content becomes greater than 2 vol %.

Referring to FIG. 9, it can be confirmed that the mechanical quality factor of Example 1 is greater than the mechanical quality factor of Comparative Example 2. It can be confirmed that the mechanical quality factor decreases as the seed content increases. This confirms that the seed acts as impurities.

### Evaluation Example 6: Evaluation of Electrical Properties According to Seed Content

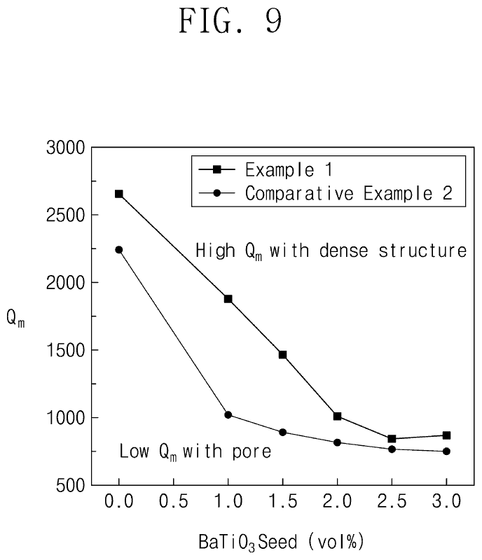

FIG. 10 shows the results of evaluating electrical properties of Example 2 while varying the BaTiO₃ seed content. Referring to FIG. 10, it can be confirmed that when the BaTiO₃ seed content is 1.0 vol % to 2.0 vol %, the piezoelectric constant is 400 pC/N or greater, the electromechanical coupling factor (Kp) is 50% or greater, and the mechanical quality factor (Qₘ) is 1000 or greater.

### Evaluation Example 7: Vibration Rate According to Electric Field Change

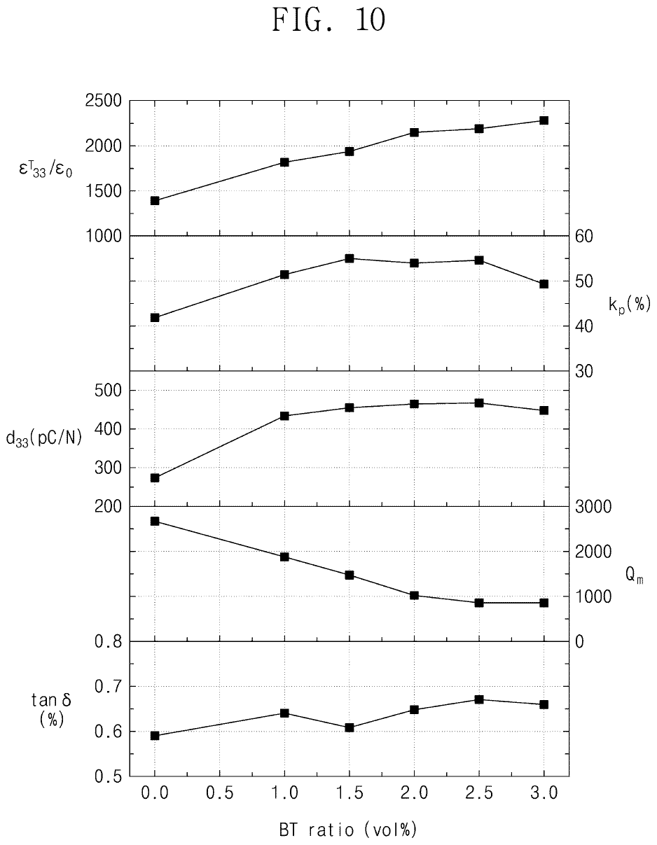

Vibration rates of the piezoelectric material compositions of Example 1, Comparative Example 1, and Comparative Example 2 were measured using a laser doppler vibrometer (LDV). FIG. 11 shows the results of measuring vibration rates of the piezoelectric material compositions of Example 1, Comparative Example 1, and Comparative Example 2 according to electric field changes. Referring to FIG. 11, it can be confirmed that Example 1 has a higher vibration rate than Comparative Example 1 and Comparative Example 2.

Therefore, it can be confirmed that Example 1 exhibits higher output than Comparative Example 1 and Comparative Example 2.

### Evaluation Example 9: Temperature Change According to Vibration Rate

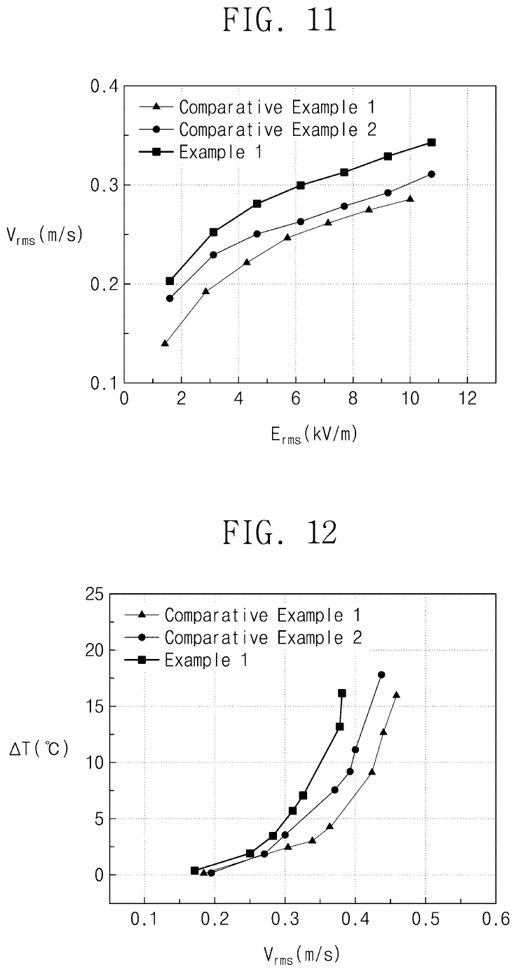

FIG. 12 shows the results of measuring temperature changes of the piezoelectric material compositions of Example 1, Comparative Example 1, and Comparative Example 2 according to vibration rates. Referring to FIG. 12, it can be confirmed that the temperature of the piezoelectric material composition of Example 1 increases at a higher vibration rate. In addition, in the case of Example 2, it can be confirmed that a high vibration rate of 0.45 m/s is exhibited.

Therefore, it can be confirmed that Example 1 exhibits higher output than Comparative Example 1 and Comparative Example 2.

### Evaluation Example 10: Comparison of Piezoelectric Performance Indices

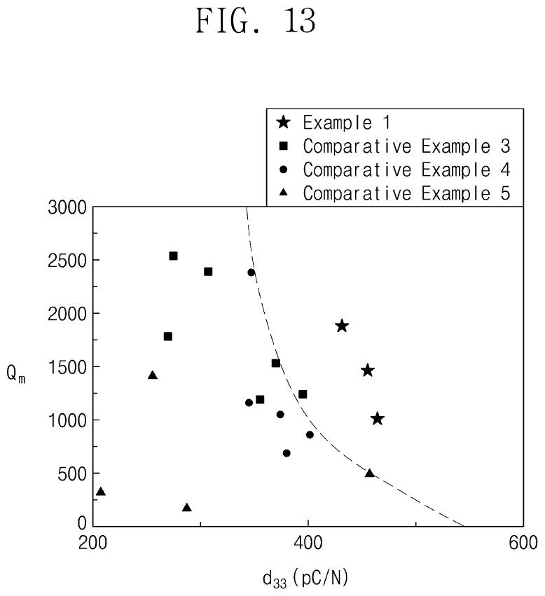

FIG. 13 shows the comparison of piezoelectric performance indices of Example 1 and Comparative Examples 3 to 5. Referring to FIG. 13, it can be confirmed that Example 1 has a higher piezoelectric performance index than Comparative Examples 3 to 5.

According to embodiments of the present invention, a Mn-doped PMN-PT piezoelectric material composition may be provided. Due to an effect of doping the Mn, a piezoelectric material composition having a high piezoelectric constant (d₃₃) and a high mechanical quality factor (Qₘ) may be provided.

The piezoelectric material composition may be oriented by a template grain growth method using a seed having a perovskite grain structure. Therefore, the above piezoelectric material composition may have increased domain alignment, and may have a perovskite grain structure; and

Furthermore, the piezoelectric material composition may be sintered in an oxygen atmosphere. As a result, the porosity of the piezoelectric material composition may be decreased. Therefore, the density of the piezoelectric material composition may be improved, and a piezoelectric material composition having a high mechanical quality factor (Qₘ) may be provided.

Although the embodiments of the present invention have been described with reference to the accompanying drawings, those skilled in the art will understand that the present invention can be implemented in other specific forms without changing the technical spirit or essential features thereof. It is therefore to be understood that the above-described embodiments are illustrative in all aspects and not restrictive.

What is claimed is:

1. A piezoelectric material composition comprising a first material doped with 2 mol % to 3 mol % of Mn based on 100 mol % of the total composition, and represented by [Formula 1] below: 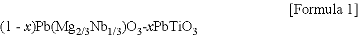
wherein the x is 0.21 to 0.25.

2. The piezoelectric material composition of claim 1, further comprising a second material comprising BaTiO₃, wherein the content of the second material is 0.5 vol % to 2.5 vol % based on 100 vol % of the piezoelectric material composition.

3. The piezoelectric material composition of claim 2, wherein the first material surrounds the second material.

4. The piezoelectric material composition of claim 1, wherein the first material is grain-oriented in a (001) direction.

5. The piezoelectric material composition of claim 1, wherein the x is 0.23.

6. The piezoelectric material composition of claim 1, wherein 2 mol % of the Mn is doped based on the total composition.

7. The piezoelectric material composition of claim 2, wherein the content of the second material is 1.5 vol % based on 100 vol % of the piezoelectric material composition.

8. The piezoelectric material composition of claim 1, wherein the piezoelectric constant (d₃₃) is 350 pC/N to 450 pC/N, and the mechanical quality factor (Qₘ) is 1400 to 2500.

9. The piezoelectric material composition of claim 1, wherein the first material has a perovskite grain structure.

10. The piezoelectric material composition of claim 1, wherein the porosity is 0.1% to 3%.

11. The piezoelectric material composition of claim 1, wherein the first material has a monoclinic structure.

12. The piezoelectric material composition of claim 11, wherein the space group of the monoclinic structure comprises Cm and Pm.

13. A piezoelectric material composition comprising a plurality of grains,
wherein:
each of the plurality of grains is distinguished from each other by a grain boundary; and
each of the plurality of grains includes a first material doped with 2 mol % to 3 mol % of Mn based on 100 mol % of the total composition, and represented by Formula 1 below: 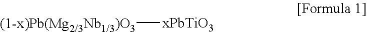
wherein the x is 0.21 to 0.25.

14. The piezoelectric material composition of claim 13, wherein each of the plurality of grains further comprises a second material having a perovskite grain structure.

15. The piezoelectric material composition of claim 14, wherein the second material comprises BaTiO₃.

16. The piezoelectric material composition of claim 13, wherein:
the x is 0.23; and
2 mol % of the Mn is doped based on 100 mol % of the total composition.

17. A method for preparing a piezoelectric material composition, the method comprising:
mixing MgNb₂O₆ and PbO, TiO₂, and MnO₂ to form a first material doped with Mn and represented by Formula 1 below;
mixing the first material and a second material in a solvent to prepare a slurry;
tape-casting the slurry to form a piezoelectric sheet;
laminating the piezoelectric sheet; and
sintering the piezoelectric sheet in an oxygen atmosphere,
wherein:
2 mol % to 3 mol % of the Mn is doped based on 100 mol % of the first material;
the second material is a seed having a perovskite structure; and
the content of the second material is 0.5 vol % to 1.5 vol % based on 100 vol % of the slurry: 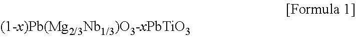
wherein the x is 0.21 to 0.25.

18. The method of claim 17, wherein the content of the second material is 1.5 vol % based on 100 vol % of the slurry.

19. The method of claim 17, wherein the x is 0.23.

20. The method of claim 17, wherein the sintering in an oxygen atmosphere is performed at 1100° C. to 1300° C.
